(19) United States
(12) Patent Application Publication
(10) Pub. No.: US 2006/0165144 A1
(43) Pub. Date: Jul. 27, 2006

(54) Semiconductor laser device

(76) Inventors: Aleksei Mikhailov, Dortmund (DE); Paul Alexander Harten, Essen (DE); Wieland Hill, Dortmund (DE)

Correspondence Address: HOFFMAN WASSON & GITLER, P.C;CRYSTAL CENTER 2, SUITE 522, 2461 SOUTH CLARK STREET, ARLINGTON, VA, 22202-3843, US

(21) Appl. No.: 10/526,217

(22) PCT Filed: Aug. 1, 2003
(86) PCT No.: PCT/EP03/08526

§ 371 Date: Aug. 2, 2005

(30) Foreign Application Priority Data
Oct. 25, 2002 (DE) 102 50 046.0
Sep. 2, 2002 (DE) 102 40 949.8
Oct. 25, 2002 (DE) 102 50 048.7

(51) Int. Cl. H01S 5/00

(52) U.S. Cl. 372/50.12

(57) ABSTRACT

The invention relates to a semiconductor laser devcie, including a semiconductor laser element, or a number of individual lasers mounted parallel to each other, with a number of output surfaces, from which laser light can escape, having a treater divergence in a first direction (Y) than in a second direction parallel to the above and at least one reflecting means, at a distance from the output surfaces, outside the semiconductor laser element or the individual laser, with at least one reflective surface which reflects at least a part of the laser light escaping from the semiconductor laser element or the individual lasers through the output surfaces back into the semiconductor laser element or the individual lasers, such that the mode spectrum of the semiconductor laser element or the individual lasers is influenced. The at least one reflective surface of the reflecting means has a concave curve.

### BACKGROUND OF THE INVENTION

This invention relates to a semiconductor laser device including a semiconductor laser element or a plurality of individual lasers mounted in parallel with a plurality of exit surfaces from which laser light can emerge, which in a first direction has greater divergence than in the second direction which is perpendicular to it, and at least one reflection means which is located spaced apart from the exit surfaces outside of the semiconductor laser element or the individual lasers, with at least one reflecting surface which can reflect back at least parts of the light which has emerged from the semiconductor laser element or the individual lasers through the exit surfaces into the semiconductor laser element or the individual lasers such that the mode spectrum of the semiconductor laser element or of the individual lasers is influenced thereby.

A semiconductor laser device of the aforementioned type is known from I. Nelson, B. Chann, T. G. Walker, Opt. Lett. 25, 1352 (2000). In the semiconductor laser device described in it, an external resonator is used which uses a grating as the reflection means. Furthermore, in the external resonator directly following the semiconductor laser element is the fast axis collimation lens. Between the fast axis collimation lens and the grating there are two lenses which are used as a telescope. The disadvantage in this semiconductor laser device is that on the one hand due to the many optical components within the external resonator comparatively high losses occur so that the output power of the semiconductor laser device is comparatively low. On the other hand, with the semiconductor laser device known from the prior art only the longitudinal modes of the semiconductor laser element or of the individual emitters of the semiconductor laser element can be influenced. The transverse mode spectrum of the semiconductor laser device cannot be influenced by the structure known from the art. For this reason this semiconductor laser device known from the art per emitter has a host of different transverse modes which all contribute to the laser light emitted from the semiconductor laser device. For this reason the laser light emerging from the semiconductor laser device according to this prior art can only be focussed with difficulty.

According to the art, an attempt is made to influence the mode spectrum of the semiconductor laser elements by structuring the active zone of the semiconductor laser element. This structuring can includes for example, changes of the refractive index in different directions, so that propagation of individual preferred transverse laser modes is preferred by these refractive indices which change in different directions. Furthermore it is possible, for example by different degrees of doping, to act on the number of electron-hole pairs available for recombination so that at different locations of the active zone different amplifications of the laser light are possible. The two aforementioned methods for giving preference to individual transverse modes are associated with considerable production cost and likewise do not yield actually satisfactory beam quality or output power of the semiconductor laser device.

An object of this invention is to devise a semiconductor laser device of the initially mentioned type which has high output power with improved beam quality.

### SUMMARY OF THE INVENTION

This is achieved as described in the invention in that at least one reflecting surface of the reflection means is concavely curved.

In this way, compared to the above described art, additional lenses within the external resonator can be omitted because the concavely curved reflecting surface can be used at the same time as an imaging element. Due to the concave curvature of the reflecting surface in particular the comparatively complex structuring of the semiconductor laser element can be omitted.

Furthermore, at least one reflecting surface can reflect back the corresponding component beams of the laser light onto the respective exit surfaces such that they are used as an aperture. The mode spectrum of the semiconductor laser element can be influenced with extremely simple means by this measure.

As in the art, the semiconductor laser device can include a lens means which is located between the reflection means and the semiconductor laser element or the individual emitters and which can at least partially reduce the divergence of the laser light at least in the first direction. This lens means is thus used as the fast axis collimation lens.

As described in the invention, it is possible for the reflection means to have a reflecting surface on which the component beams emerging from different exit surfaces can be reflected. Alternatively, the reflection means can have a host of reflecting surfaces which can each reflect the component beams emerging from the individual exit surfaces.

According to one preferred embodiment of this invention, the semiconductor laser device includes a beam transformation unit which is made especially as a beam rotation unit and preferably can rotate individual ones of the component beams at one time, especially by roughly 90°. With such a beam transformation unit the laser light emerging from the semiconductor laser device can be transformed such that it can then be focused more easily.

According to one preferred embodiment of this invention, the beam transformation unit is located between the reflection means and the semiconductor laser element or the individual lasers, in particular between the reflection means and the lens means. More room for decoupling can be formed by this arrangement of the beam transformation unit within the external resonator.

The semiconductor laser device can include a frequency-doubling element which is located between the reflection means and the semiconductor laser element or the individual lasers, especially between the reflection means and the lens means. In particular the second harmonic could be decoupled at least partially from the semiconductor laser device and the fundamental wavelength could be reflected back for influencing the mode spectrum at least partially into the semiconductor laser element or the individual lasers.

As described in the invention, it is furthermore possible for the semiconductor laser element to be exposed to a voltage and to be supplied with current for producing electron-hole pairs only in partial areas which correspond to the three-dimensional extension of the desired mode of the laser light. Giving preference to desired modes of the laser light can be further optimized by this measure which can be carried out relatively easily.

### BRIEF DESCRIPTION OF THE DRAWINGS

Other features and advantages of this invention become apparent based on the following description of preferred embodiments with reference to the attached figures.

FIG. 1 shows a schematic top view of a first embodiment of the semiconductor laser device as claimed in the invention;

FIG. 2 shows a schematic top view of a second embodiment of a semiconductor laser device as claimed in the invention;

FIG. 3 shows a schematic top view of a third embodiment of a semiconductor laser device as claimed in the invention; and

FIG. 4 shows a schematic top view of a fourth embodiment of a semiconductor laser device as claimed in the invention.

### DETAILED DESCRIPTION OF THE INVENTION

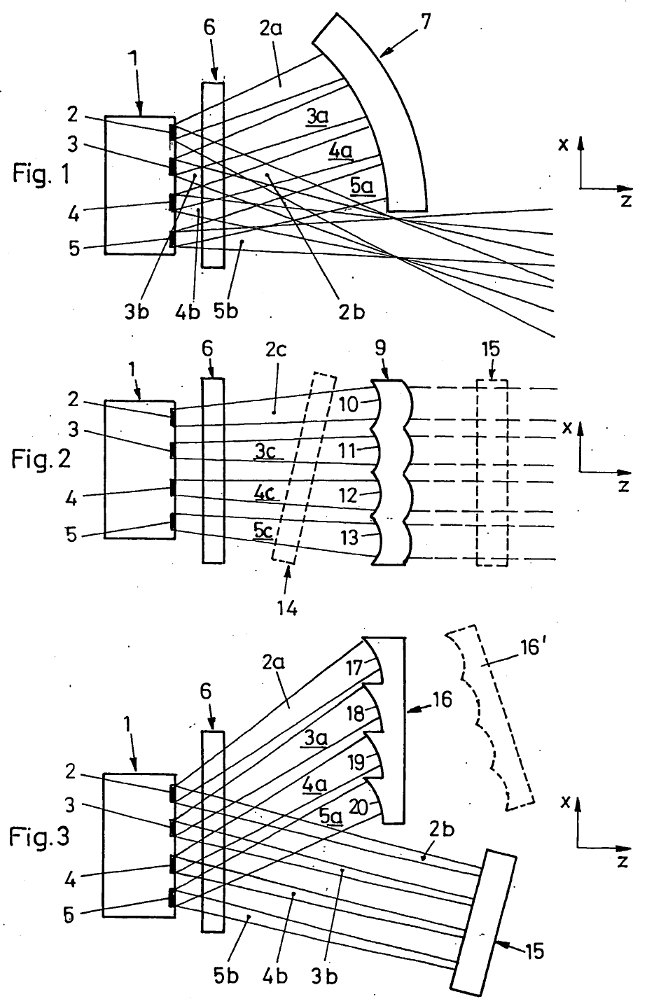

The embodiment of a semiconductor laser device as described in the invention shown in FIG. 1 includes a semiconductor laser element 1 with a host of exit surfaces 2, 3, 4, 5 from which laser light can emerge. The semiconductor laser element 1 is made as a broad strip emitter array or as a so-called laser diode bar. In the illustrated embodiment, only four exit surfaces 2, 3, 4, 5 which are separated from one another and which are used for light emission are shown. But it is quite possible for there to be a much larger number of exit surfaces which are arranged parallel and spaced apart from one another.

The laser light emerging from each of the exit surfaces 2, 3, 4, 5 is split into two component beams 2a, 2b; 3a, 3b; 4a, 4b; 5a, 5b which each include an oppositely identical angle with the normals to the exit surfaces 2, 3, 4, 5. The paired component beams 2a, 2b; 3a, 3b; 4a, 4b; 5a, 5b each represent a selected laser mode of the emitting component area of the semiconductor laser element 1 which belongs to the corresponding exit surface 2, 3, 4, 5.

As FIG. 1 shows, a semiconductor laser device as claimed in the invention furthermore comprises a lens means 6 which is made as a fast axis collimation lens, outside of the semiconductor laser element 1. The fast axis corresponds to the Y-direction in the illustrated Cartesian coordinate system. The fast axis in these broad strip emitters is the direction perpendicular to the direction in which the individual emitters are located next to one another. The divergence of such a semiconductor laser element 1 in the fast axis is much greater than in the slow axis which is perpendicular to it and which corresponds to the X direction in FIG. 1.

Downstream of the lens means 6 at a suitable distance from the semiconductor laser element 1 there is a reflection means 7 with a reflecting surface 8 which faces the semiconductor laser element 1. The component beams 2a, 3a, 4a, 5a are reflected back in the direction to the exit surfaces 2, 3, 4, 5 by the reflecting surface 8. The exit surfaces 2, 3, 4, 5 are optionally provided with a non-reflecting coating so that the component beams 2a, 3a, 4a, 5a which have been reflected back can penetrate at least partially into the semiconductor laser element 1 such that in this way the mode spectrum of the semiconductor laser element 1 is influenced. In particular, depending on the alignment, focal length and distance of the reflection means 7, with respect to the exit surfaces 2, 3, 4, 5 preference can be given to the propagation of certain modes in the semiconductor laser element 1. In the embodiment of a semiconductor laser device as described in the invention shown in FIG. 1 generally not all laser emitters which are assigned to the individual exit surfaces 2, 3, 4, 5 will oscillate at the same mode because the angles at which the illustrated component beams 2a, 3a, 4a, 5a emerge from the exit surfaces 2, 3, 4, 5 are somewhat different.

The distance of the reflecting surface 8 from the exit surfaces 2, 3, 4, 5 can be chosen such that it corresponds essentially to the focal length of the reflecting surface 8. In particular, by the corresponding choice of the distance or focal length, the beam waist on the exit surfaces 2, 3, 4, 5 can correspond roughly to their respective width.

Decoupling from the semiconductor laser device as shown in FIG. 1 can take place via the component beams 2b, 3b, 4b, 5b. For example, in FIG. 1 underneath the reflection means 7 another partially reflecting reflection means which is used as a decoupler can be inserted. In addition or alternatively, a beam transformation unit which facilitates further processing of the decoupled component beams could also be placed in the beam path of the component beams 2b, 3b, 4b, 5b.

In the embodiment of a semiconductor laser device as described in the invention shown in FIG. 2, the same parts are provided with the same reference numbers. FIG. 2 shows component beams 2c, 3c, 4c, 5c which correspond to the transverse mode of the individual emitters of the semiconductor laser element 1, which emerges from the semiconductor laser element 1 essentially parallel to the normals on the exit surfaces 2, 3, 4, 5, i.e. roughly in the Z-direction according to a Cartesian coordinate system. The reflection means 9 which is provided in FIG. 2 has not only a reflecting surface, but a host of reflecting surfaces 10, 11, 12, 13. Thus one of the reflecting surfaces 10, 11, 12, 13 is assigned to each of the component beams 2c, 3c, 4c, 5c so that in this embodiment each of the emitters of the semiconductor laser element 1 which correspond to the exit surfaces 2, 3, 4, 5 can be operated in the same transverse or longitudinal mode.

For giving preference to an individual longitudinal mode a wave-selective element 14 which can be made for example as an etalon is shown by the broken line in FIG. 2. The optional wave-selective element 14 makes it possible to choose certain longitudinal modes, especially a longitudinal mode so that the emitted laser light has a small spectral width.

Decoupling from the semiconductor laser device can be achieved either by the reflection means 9 being made partially reflective so that in the positive Z direction laser light can emerge from the reflection means 9. Alternatively, the side of the semiconductor laser element which is facing away from the external resonator which is formed by the reflection means 9 can be partially non-reflective or may not be highly reflective so that on the left side in FIG. 2 of the semiconductor laser element laser light can emerge into the negative Z direction.

According to another alternative, in FIG. 2 to the left of the semiconductor laser element 1 it is possible for there to be another reflection means which is equivalent to the reflection means 9 and which can reflect back the laser light emerging from the semiconductor laser element 1 in the negative Z direction into the semiconductor laser element 1. The external resonator in this case is formed by the two reflection means 9 with reflecting surfaces facing one another. One of the reflection means 9 can thus be made partially reflecting so that the laser light can pass through this reflection means partially for decoupling.

FIG. 2 furthermore shows by a broken line on the right side of the reflection means a beam transformation unit 15; it can transform the beam when light emerges in the positive Z direction from the reflection means 9. The beam transformation unit can be for example a beam rotation unit which can turn each of the component beams 2c, 3c, 4c, 5c individually by for example 90°. The focussing capacity of the emerging laser light is improved by this beam transformation. As described in the invention it is quite possible to use such a beam transformation unit in the embodiment as shown in FIG. 1 as well.

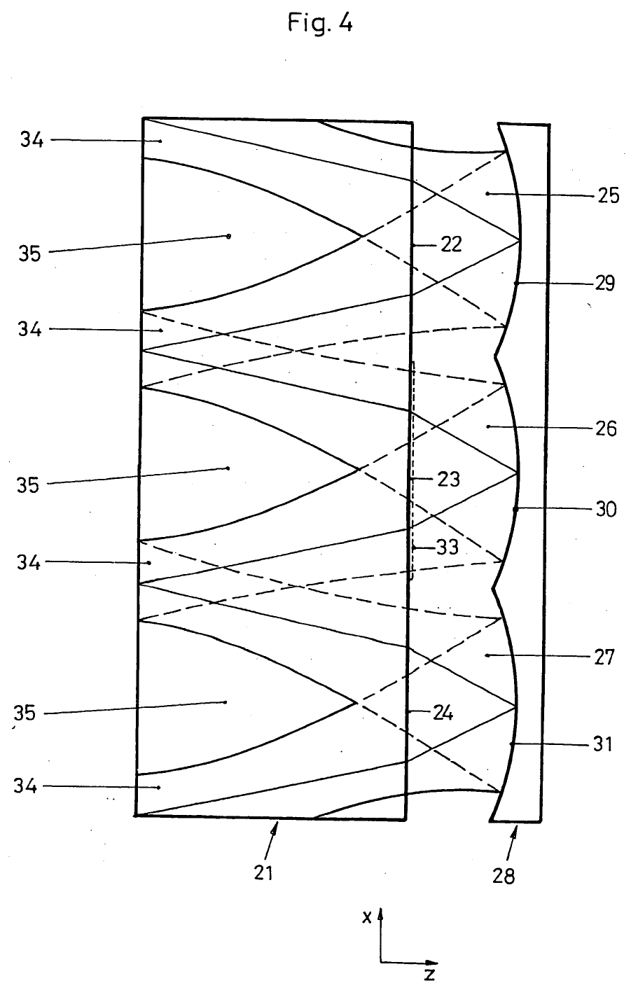

The semiconductor laser device as shown in FIG. 3 differs from the one in FIG. 2 essentially in that the modes are preferred which according to FIG. 1 emerge at an angle to the normal from the exit surfaces 2, 3, 4, 5. The reflection means 16 which is provided in the semiconductor laser device as shown in FIG. 3 in turn has a host of reflecting surfaces 17, 18, 19, 20. In the embodiment of the reflection means 16 which is drawn using solid lines it is oriented essentially parallel to the X direction so that the paths of the individual component beams 2a, 3a, 4a, 5a between the exit surfaces 2, 3, 4, 5 and the reflecting surfaces 17, 18, 19, 20 are the same. Alternatively, there can also be a reflection means 16′ which is shown in FIG. 3 by the dot-dash line and which can be installed in the semiconductor laser device at the same place as the reflection means 16. For such a reflection means 16′ which is aligned essentially perpendicular to the direction of propagation of the component beams 2a, 3a, 4a, 5a, the optical paths of the component beams 2a, 3a, 4a, 5a between the exit surfaces 2, 3, 4, 5 and the reflection means 16′ are different.

In the reflection means 16 the individual reflecting surfaces 17, 18, 19, 20 are tilted relative to the Z-axis. This is omitted in the reflection means 16′. In any case it can be necessary here to make the radii of curvature of the reflecting surfaces different from one another.

FIG. 3 likewise shows a beam transformation unit 15 which is located in the beams 2b, 3b, 4b, 5b which are to be decoupled. The laser light passing through this beam transformation unit 15 can be focussed for example by other focussing means onto the end of a glass fiber.

As described in the invention it is possible to provide a wavelength-selective element in the embodiments as shown in FIG. 1 and FIG. 3. For the differently tilted component beams as shown in FIG. 1 this could necessitate a curved etalon in order to select the same wavelength each time.

It is furthermore possible as described in the invention to place a beam transformation unit in the external resonator, i.e. between the respective reflection means 7, 9, 16, 16′ and the semiconductor laser element 1, especially between the lens means 6 and the reflection means 7, 9, 16, 16′. This arrangement under certain circumstances can entail the advantage that in this way more space is formed for decoupling.

A beam transformation unit which is made for example as a beam rotation unit rotates the emission of the individual emitters by 90°. After this rotation, the component beams 2a, 3a, 4a, 5a run at the same angles to the X-Z plane upward and the component beams 2b, 3b, 4b, 5b run downward at oppositely identical angles. An individual cylindrical mirror is then suited for slow axis collimation. When spherical mirrors are to be used, a mirror array is furthermore needed for slow axis collimation in this case.

If a stack of emitter arrays is used, in a structure with a beam rotation unit a one-dimensional array of cylinder mirrors for slow axis collimation could be used.

It is furthermore possible as described in the invention to house a frequency-doubling element, for example a frequency-doubling crystal, in the external resonator. For example, this element could be housed between the lens means 6 and the reflection means 9 in FIG. 2. In this case the reflecting surfaces 10, 11, 12, 13 can be highly reflective for the fundamental wavelength and permeable to the wavelength of the second harmonic. Under certain circumstances the lens means 6 could also be made such that the fundamental wavelength is transmitted unhindered and the second harmonic is reflected so that the second harmonic is not coupled back into the semiconductor laser element 1.

It is possible as described in the invention to use a stack of emitter arrays as the semiconductor laser element 1. In this case for example a two-dimensional array of spherical or cylindrical mirrors or a one-dimensional array of spherical mirrors can be used. Here the distance and the focal length can be determined according to the statements regarding FIG. 1.

It is furthermore possible to use a host of separate individual lasers mounted in parallel instead of a semiconductor laser element 1 which is made as a laser diode bar. They could be operated as single mode lasers and could be triggered individually. This host of individual lasers is especially suited for applications in medical technology.

FIG. 4 shows a semiconductor laser element 21 which is made as a laser diode bar. The semiconductor laser element 21 has a host of exit surfaces 22, 23, 24 from which laser light 25, 26, 27 can emerge. Furthermore, in the embodiment as shown in FIG. 4 there is a reflection means 28 which has a host of reflecting surfaces 29, 30, 31 which are located next to one another and which for example are made like the reflecting surface 10, 11, 12, 13 as shown in FIG. 2. Like in the embodiment as shown in FIG. 2 the reflecting surfaces 29, 30, 31 reflect back the corresponding portion of the laser light 25, 26, 27 through the pertinent exit surfaces 22, 23, 24 into the semiconductor laser element 21. In the selected mode of the laser light shown in FIG. 4 each of the reflecting surfaces 29, 30, 31 reflects back the component beams of the respective laser light 25, 26, 27 into the semiconductor laser element 21 such that they are reflected at an angle to the normal on the opposite end surface 32 of the semiconductor laser element so that they emerge after this reflection from the adjacent exit surface 22, 23, 24. In this way it becomes possible for essentially a single mode of the laser light to be formed in the overall semiconductor laser element 21.

For example, it can also be provided that individual exit surfaces, such as for example the exit surface 23 which is the middle one in FIG. 4, be provided with a highly reflecting coating 33 so that light from the semiconductor laser element cannot emerge from this exit surface 23. The light in this case is reflected on this exit surface and after further reflection on the opposing end surface 32 emerges through one of the adjacent exit surfaces 22, 24 from the semiconductor laser element 21.

In the embodiment as shown in FIG. 4, it can be provided that only certain partial areas 34 of the semiconductor laser element 21 are provided with electrodes so that only these partial areas 34 are exposed to a voltage and thus current is supplied only in these partial areas 34 to produce electron-hole pairs. FIG. 4 furthermore shows partial areas 35 which are not provided with electrodes and accordingly cannot be supplied with voltage either. This configuration optimizes the execution of one or more preferred modes. It is possible to place a lens means which is not shown in FIG. 4 between the reflection means 28 and the semiconductor laser element 21.

What is claimed is:

1. A semiconductor laser device comprising a semiconductor laser element or a plurality of individual lasers mounted in parallel with a plurality of exit surfaces from which laser light can emerge which in a first direction (Y) has greater divergence than in the second direction which is perpendicular to it; and at least one reflection means which is located spaced apart from the exit surfaces outside of the semiconductor laser element or of the plurality of individual lasers, with at least one reflecting surface which can reflect back at least parts of the laser light which has emerged from the semiconductor laser element or the plurality of individual lasers through the exit surfaces into the semiconductor laser element or the plurality of individual lasers such that the mode spectrum of the semiconductor laser element or of the individual lasers is influenced thereby; wherein at least one reflecting surface of the reflection means is concavely curved.

2. The semiconductor laser device as claimed in claim 1, wherein at least one reflecting surface can reflect back component beams of laser light onto the exit surfaces such that they are used as an aperture.

3. The semiconductor laser device as claimed in claim 1, wherein the semiconductor laser device comprises a lens means which is located between the reflection means and the semiconductor laser element or the plurality of individual lasers and which can at least partially reduce the divergence of the laser light at least in the first direction (Y).

4. The semiconductor laser device as claimed in claim 1, wherein the at least one reflection means has a reflecting surface on which component beams emerging from different exit surfaces can be reflected.

5. The semiconductor laser device as claimed in claim 1, wherein the at least one reflection means has a host of reflecting surfaces which can each reflect the component beams (2a, 2c; 3a, 3c; 4a, 4c; 5a, 5c) emerging from the individual exit surfaces (2, 3, 4, 5, 22, 23, 24).

6. The semiconductor laser device as claimed in claim 1, wherein the semiconductor laser device comprises a beam transformation unit which is a beam rotation unit and can rotate individual ones of the component beams at one time, by roughly 90°.

7. The semiconductor laser device as claimed in claim 6, wherein the beam transformation unit is located between the at least one reflection means and the semiconductor laser element or the Plurality of individual lasers, between the at least one reflection means and the lens means.

8. The semiconductor laser device as claimed in claim 1, wherein the semiconductor laser device further comprises a frequency-doubling element which is located between the at least one reflection means and the semiconductor laser element or the plurality of individual lasers, between the at least one reflection means and the lens means.

9. The semiconductor laser device as claimed in claim 1, wherein the semiconductor laser element is exposed to a voltage and is supplied with current for producing electron-hole pairs only in partial areas which correspond to the three-dimensional extension of the desired mode of the laser light.
